(19) United States
(12) Patent Application Publication
(10) Pub. No.: US 2008/0257260 A9
(43) Pub. Date: Oct. 23, 2008

(54) Batch wafer handling system

(75) Inventors: Adam A. Brailove, Gloucester, MA (US); Aaron Webb, Austin, TX (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 11/242,301

(22) Filed: Sep. 30, 2005

(51) Int. Cl. C23C 16/00

(52) U.S. Cl. 118/719; 427/248.1

(57) ABSTRACT

The present invention generally provides a batch processing system having a processing chamber and a loading chamber. Substrates are transferred in and out the processing chamber in a batch by a substrate boat. A batch handling tool of the present invention is generally used in the loading chamber to load and unload the structured substrate support by group. The batch handling tool generally comprises a support member, which is configured to host at least two sets of support blades. The at least two sets of substrate supports are generally mounted on the support member and their positions are switchable when the support member rotates. Each set of the support blades is configured to load (unload) at least two substrates into(from) the substrate boat.

### BACKGROUND OF THE INVENTION

1. Field of the Invention

Embodiments of the present invention generally relate to methods and apparatus for transferring substrates during batch processing.

2. Description of the Related Art

The effectiveness of a substrate fabrication process is often measured by two related and important factors, which are device yield and the cost of ownership (COO). These factors are important since they directly affect the cost to produce an electronic device and thus a device manufacturer's competitiveness in the market place. The COO, while affected by a number of factors, is greatly affected by the system and chamber throughput or simply the number of substrates processed per hour and cost of the processing material. Batch processing is very effective in terms of reducing COO.

The term batch processing generally indicates a process step that can process two or more substrates simultaneously. The advantages of batch processing are generally two-fold. On the one hand, batch processing can increase system throughput by performing a process recipe step that is disproportionately long compared to other process recipe steps in a substrate processing sequence. On the other hand, in some processing steps, such as ALD and CVD, where expensive precursor materials are used, batch processing can greatly reduce usage of precursor gases compared to single substrate processing, hence reducing COO.

A batch processing chamber may be configured to perform a batch semiconductor process, such as for example atomic layer deposition (ALD), chemical vapor deposition (CVD), plasma oxidation, ion implantation. In one aspect, a batch processing chamber may be used to increase system throughput by performing a process recipe step that is disproportionately long compared to other process recipe steps in the substrate processing sequence that are performed on a cluster tool. In another aspect, two or more batch chambers are used to process multiple substrates using one or more of the disproportionately long processing steps in a processing sequence.

FIG. 1 is a schematic sectional view of a batch processing system 100 of the prior art. The batch processing system 100 generally comprises a process chamber 101 configured to perform a batch semiconductor process, such as for example atomic layer deposition (ALD), chemical vapor deposition (CVD), plasma oxidation, ion implantation. The process chamber 101 is generally in communication with gas delivery facilities 115 configured to deliver process materials, heating devices 116 configured to heat substrates and process materials, and pumping devices 117. The process chamber 101 is generally in selective fluid communication with a load lock 102 in which a substrate boat 106, configured to transfer a batch of substrates 140 to and from the process chamber 101 and support the substrates 140 during process, may be loaded/unloaded. The substrate boat 106 may be constructed of any suitable high temperature material such as, for instance, quartz, silicon carbide, or graphite, depending upon desired process characteristics. An O-ring structure 103 is generally disposed between the process chamber 101 and the load lock 102. The load lock 102 may be connected to the pumping devices 117. A shaft 118 is generally disposed in a rotary seal 108 positioned on a bottom wall of the load lock 102. The shaft 118 is connected to a lifting and rotating mechanism 110 on one end and connected to the substrate boat 106 on the other end such that the lifting and rotating mechanism 110 is able to rotate the substrate boat 106 and translate the substrate boat 106 vertically. A circular seal plate 104 configured to seal the process chamber 101 from the load lock 102 is generally positioned around the shaft 118 and bellow the substrate boat 106. A quartz ring 105 nested into a groove around an outer periphery of a top surface of the circular seal plate 104. A lifting mechanism 109 may be connected to the circular seal plate 104 and translate it vertically.

A slit valve opening 111 is generally attached to a side wall 119 of the load lock 102. Through the slit valve opening 111, a robot 113 disposed in a chamber 112 may insert (remove) a substrate into (from) the load lock 102. In one aspect, the chamber 112 may be a vacuum chamber. In another aspect, the chamber 112 may be a factory front environment. The chamber 112 may further connect to one or more load ports 114 configured to store substrates. The batch processing system 100 may comprise a system controller 120 configured to optimize the system.

Examples of hardware and methods used to perform a batch process is further described in U.S. Pat. No. 6,352,593, entitled “Mini-batch Process Chamber” filed Aug. 11, 1997, and U.S. patent application Ser. No. 10/216,079, entitled “High Rate Deposition At Low Pressure In A Small Batch Reactor” filed Aug. 9, 2002, which are hereby incorporated by reference in their entireties.

In operation, the substrate boat 106 loaded with unprocessed substrates may be elevated into the process chamber 101 completely. The seal plate 104 is also lifted into intimate contact with an inner lip of the O-ring structure 103. When the quartz ring 105 is in intimate contact with the O-ring structure 103, the seal plate 104 provides an almost complete seal between the process chamber 101 and the load lock 102. The process chamber 101 may then be pumped down, supplied with processing materials and perform a batch process step. And the batch processing system 100 is in a process position. Upon finishing the process step performed in the process chamber 101, the process chamber 101 may be pumped out, the seal plate 104 may be lowered and the substrate boat 106 may be lowered down. The batch processing system 100 is then in a loading/unloading position, as illustrated in FIG. 1. In the loading/unloading position, the robot 113 can shuttle the substrates 140 between the substrate boat 106 and the load port 114 one by one and the process chamber 101 stays idle.

Although the usage of a batch processing chamber reduces processing time by processing a batch of substrates simultaneously, loading and unloading process, during which the batch processing chamber stays idle, takes extra time since the substrates are generally handled one by one by a robot. The loading and unloading process may take even longer when cooling down of processed substrates and preheating of unprocessed substrates are required in a step recipe. In one aspect, the loading and unloading process increases COO because it keeps the batch processing chamber idle. In another aspect, the substrate boat cools off during the loading and unloading process. Differential thermal expansion between the substrate boat and the film deposited thereon is very likely to cause the deposited film to flake off and generate particle contaminations. Swappable substrate boats may be used to cut the idle time of the batch processing chamber. However, the swappable substrate boats may be complicated and expensive. In one aspect, each substrate boat generally needs to be lifted and rotated independently and swapping the substrate boats generally requires complex mechanism. On another aspect, substrate boats are consumable components and need to be cleaned and replaced periodically. So there is additional cost for a second substrate boat. Alternatively, a batch handling tool that can transfer a batch of substrates into/from a substrate boat simultaneously shortens idle time of a batch processing chamber with one substrate boat, thus, increases system throughput and reduces COO without engaging a complicated boat system.

Therefore, there is a need for a system, a method and an apparatus that can transfer substrates effectively during batch processing.

### SUMMARY OF THE INVENTION

The present invention generally provides a batch processing system having a processing chamber and a loading chamber, for example, a load lock. Substrates are transferred in and out the processing chamber in a batch by a structured substrate support, for example, a substrate boat. A batch handling tool of the present invention is generally used in the loading chamber to load and unload the structured substrate support by group. The batch handling tool generally comprises a frame, for example, a support member, which is configured to host at least two sets of substrate supports, for example, support blades. The at least two sets of substrate supports are mounted on the frame in a radial manner such that their positions are switchable when the frame rotates or pivots. Each set of the substrate supports is configured to load(unload) at least two substrates into(from) the structured substrate support. Generally, at least one set of the substrate supports are empty when the batch handling tool is loaded with a batch of substrates so that the batch handling tool may unload substrates from the structured substrate support and load the structured substrate support without communicating with substrate storage outside the loading chamber.

One embodiment of the present invention provides a batch handling tool for supporting and transferring substrates during batch processing. The batch handling tool comprises at least two sets of support blades configured to support the substrates, a support member on which the at least two sets of support blades are mounted, and a rotating mechanism configured to switch positions of the at least two sets of support blades about the support member and to transfer the support member.

A second embodiment of the present invention provides a batch processing system. The batch processing system comprises a process chamber, a load lock in selective fluid communication with the process chamber, a substrate boat configured to support and transfer a set of substrates between the process chamber and the load lock, and a batch handling tool disposed in the load lock configured to load and unload the substrate boat at least two substrates at a time.

Another embodiment of the present invention comprises a method for transferring and supporting substrates in a batch processing system. The method comprises loading a batch handling tool having at least two sets of support blades with a batch of unprocessed substrates, receiving in the batch handling tool a batch of processed substrates from a substrate boat, transferring the batch of unprocessed substrates to the substrate boat and starting a batch processing step, and unloading the batch of processed substrates from the batch handling tool.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a batch processing chamber with substrate handling system (prior art).

FIG. 2 is a schematic sectional side view of an exemplary batch processing system with a batch substrate handling tool.

FIG. 3 is a schematic sectional top view of the batch processing system shown in FIG. 2.

FIG. 4 is a schematic view of the batch processing system shown in FIG. 2 in a loading/unloading position.

FIG. 5 is a schematic top view of the batch processing system shown in FIG. 4.

FIG. 6 illustrates an exemplary batch processing system having a batch handling tool.

FIG. 7 illustrates a top view of the batch processing system of FIG. 6.

FIG. 8 illustrates a top view of the batch processing system of FIG. 6.

FIG. 9 illustrates an exemplary batch processing system having a batch handling tool.

FIG. 10 illustrates a top view of the batch processing system of FIG. 9.

FIG. 11 illustrates a top view of the batch processing system of FIG. 9.

FIG. 12 illustrates a loading and unloading sequence of a batch handling tool with three sets of blades.

FIG. 13 illustrates a loading and unloading sequence of a batch handling tool with two or more sets of blades.

### DETAILED DESCRIPTION

The present invention generally provides an apparatus and method for handling and transferring substrates in a batch processing system. A batch processing system generally describes a system that can process two or more substrates in one processing region. In one aspect of the invention, a batch handling tool is utilized to transfer substrates in batch to and from a substrate boat. The invention is illustratively described below in reference to modification of a FlexStar™ system, available Applied Materials, Inc., Santa Clara, Calif.

Although the usage of a batch processing chamber reduces processing time by processing a batch of substrates simultaneously, loading and unloading take extra time during which the batch processing chamber stays idle since the substrates are generally handled one by one by a robot. A batch handling tool that can transfer a batch of substrates into/from a substrate boat simultaneously shortens idle time of a batch processing chamber with one substrate boat, thus, increases system throughput and reduces COO without engaging a complicated boat system. Since the batch handling tool can load and unload a substrate boat in batch, the substrate boat can stay hot between batches. Therefore, the batch handling tool can not only shorten a batch chamber's idle time but also reduce particle contaminations caused by differential thermal expansion between a substrate boat and films deposited thereon.

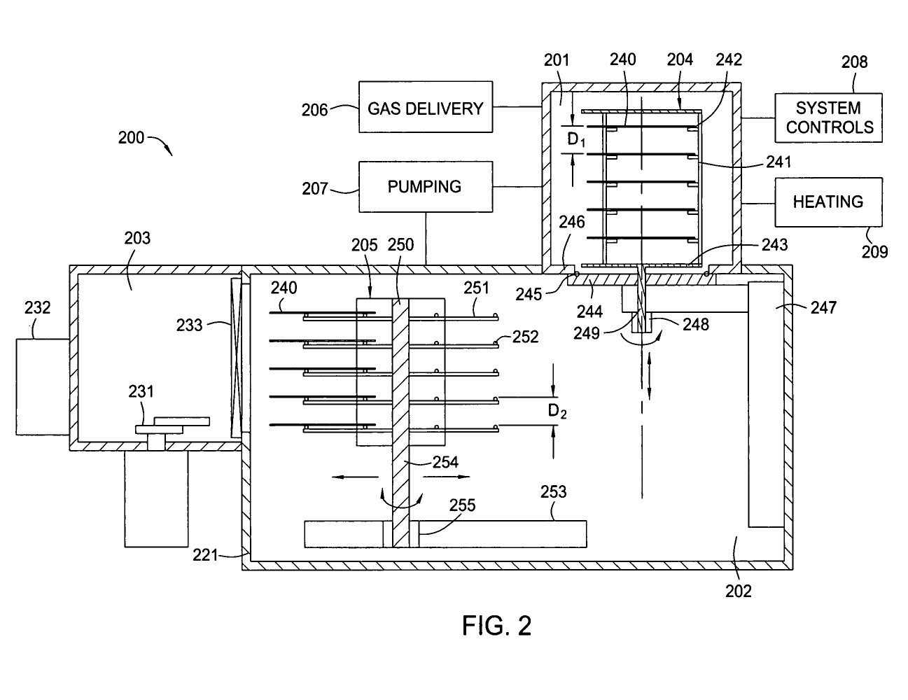

FIGS. 2-5 illustrate one embodiment of a batch processing system 200 having a batch handling tool. Referring to FIG. 2, the batch processing system 200 generally comprises a process chamber 201 configured to perform a batch semiconductor process, such as for example ALD, CVD, plasma oxidation, and ion implantation. A number of N1 substrates may be processed by the batch processing system 200. The process chamber 201 is generally in communication with gas delivery facilities 206 configured to deliver process materials, heating devices 209 configured to heat substrates and process materials, and pumping devices 207. In one aspect, the batch processing system 200 may have a system controller 208 configured to optimize the process.

The process chamber 201 is generally in selective fluid communication with a load lock 202 in which a substrate boat 204, configured to transfer a batch of substrates 240 in and out the process chamber 201 and support the substrates 240 during process, may be loaded/unloaded. In one aspect, the process chamber 201 and the load lock 202 may be vertically stacked together. In this case, the process chamber 201 is positioned above the load lock 202. For processes that require expensive processing materials (gases), reducing pumping volume in a process chamber generally results in reducing COO. Therefore, a batch process chamber is generally constructed as small as possible. In this case, the process chamber 201 may be much smaller than the load lock 202.

During a batch process, a batch of substrates are generally disposed in a process chamber with processing surface exposed. Typically, a vertical substrate boat configured to hold a plurality of substrates in a stacked manner is used to shuttle the batch of substrates in and out prior to or after the process and to support the substrates during the process. A typical substrate boat also rotates during the process to achieve even distribution of heat transferring and mass flow. In one aspect, the substrate boat 204 is a vertical boat having a plurality of support rods 241 vertically attached to a base member 243. A set of support fingers 242 are generally formed on each of the plurality of the support rods 241. In one aspect, the set of support fingers 242 are evenly distributed along the length of the support rod 241 and a distance between a top surface of each support finger 242 to a top surface of its vertically neighboring fingers 242 is D1.

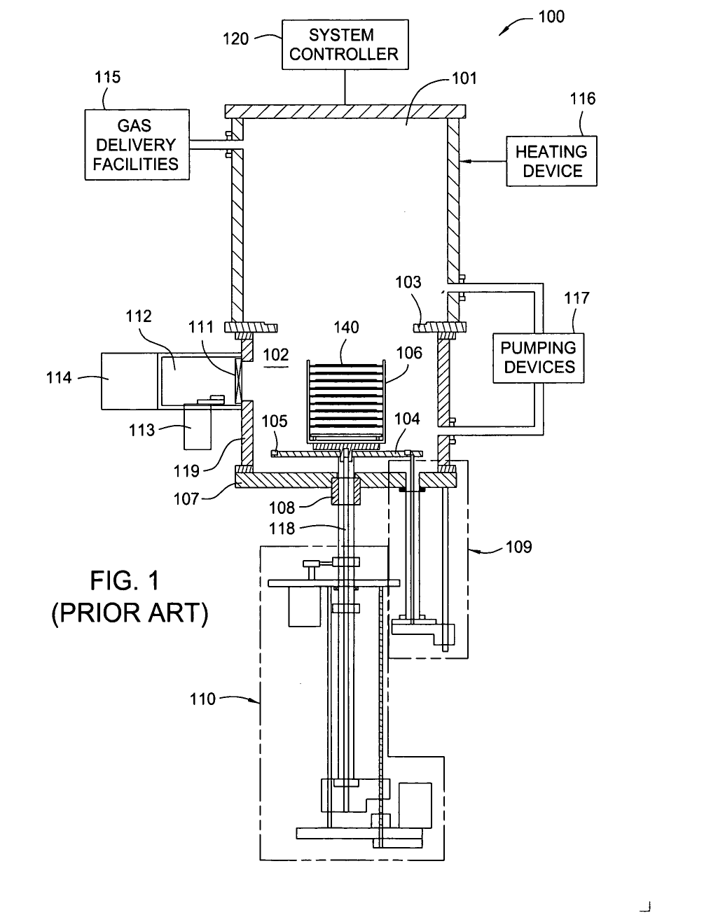

Referring now to FIG. 2, the support rods 241 are generally arranged along a perimeter of the base member 243. The perimeter is generally larger than a perimeter of a substrate and the support fingers 242 are generally reaching inwards such that a point near an edge of a substrate may be rested on tips of the support fingers 242. In one aspect, the support rods 241 may be arranged that two neighboring support rods 241 may have a distance larger than a diameter of a substrate so that the substrate may be slide into the substrate boat 204 horizontally. Referring back to FIG. 1, the support fingers 242 form a plurality of horizontal planes having an interval distance of Dl, on which the batch of substrates 240 may be positioned. The base member 243 is generally connected to a shaft 249 through which the substrate boat 204 may be translated vertically and rotated. The substrate boat 204 may be constructed of any suitable high temperature material such as, for instance, quartz, silicon carbide, or graphite, depending upon desired process characteristics.

An O-ring structure 246 is generally disposed between the process chamber 201 and the load lock 202. In one aspect, a seal plate 244 configured to seal the process chamber 201 from the load lock 202 may be generally disposed around the shaft 249 underneath the base member 243. A quartz ring 245 is generally nested into a groove around an outer periphery of a top surface of the circular seal plate 244. The shaft 249 may be connected to a lifting mechanism 247 configured to vertically translate the substrate boat 204 and a rotating mechanism 248 configured to rotate the substrate boat 204. In one aspect, the lifting mechanism 247 and the rotating mechanism 248 may be disposed in the load lock 202. In another aspect, the lifting mechanism 247 and the rotating mechanism 248 may be disposed outside the load lock 202. The lifting mechanism 247 may be actuated by hydraulic, pneumatic or electrical motor/lead screw mechanical actuators all well known in the art. In one aspect, the rotating mechanism 248 may be a servo motor. In another aspect, the rotating mechanism 248 may be actuated by a pneumatic actuator.

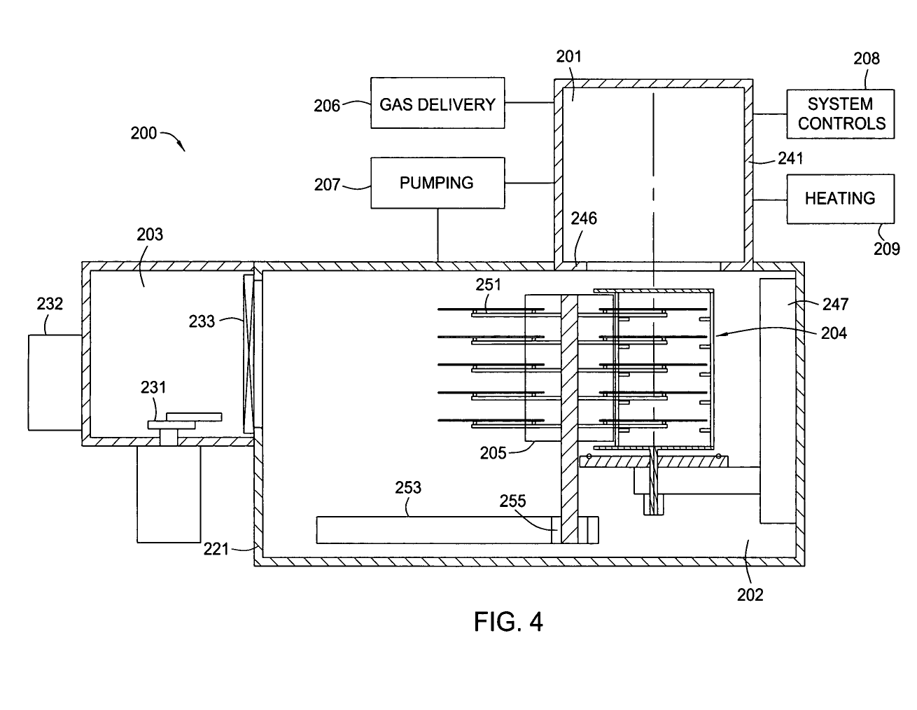

The substrate boat 204 and the seal plate 244 may be elevated such that the substrate boat 204 is completely inside the process chamber 201 and the quartz ring 245 is in intimate contact with an inner lip of the O-ring structure 246. In this case, the seal plate 244 provides an almost complete seal between the process chamber 201 and the load lock 202 and the batch processing system 200 is in a process position as illustrated in FIG. 1. When the seal plate 244 is lowered down, and the process chamber 201 is in fluid communication with the load lock 202, the batch processing system 200 is in a loading/unloading position, as illustrated in FIG. 4.

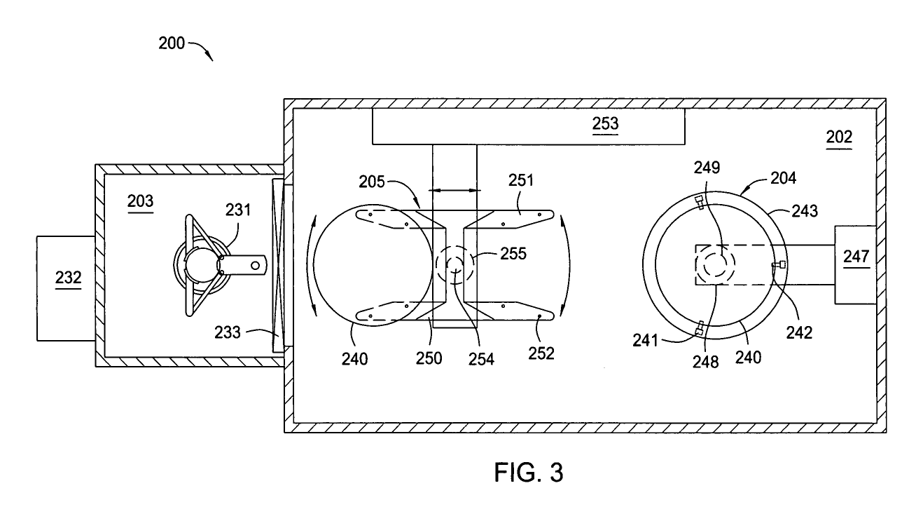

An exemplary batch handling tool 205 is generally disposed in the load lock 202. The batch handling tool 205 generally comprises a support member 250 on which two sets of support blades 251 each configured to support a batch of substrates are mounted. In one aspect, each set contains a number of N1 support blades 251. In one aspect, the two sets of support blades 251 may be mounted on the support member 250 in a back to back manner such that the two sets of support blades 251 switch positions if the support member rotates 180° degrees, as illustrated in FIG. 3. Contact pins 252 are generally formed on each of the support blades 251 such that each substrate held by the support blades 251 may be supported by at least three contact pins 252. The contact pins 252 reduce physical contact area between the support blades 251 and the substrates 240 thereon which reduces particle contamination. Referring back to FIG. 2, the support blades 251 are distributed along the length of the support member 250 at a distance D2 which is substantially equal to the distance D1 of the substrate boat 204.

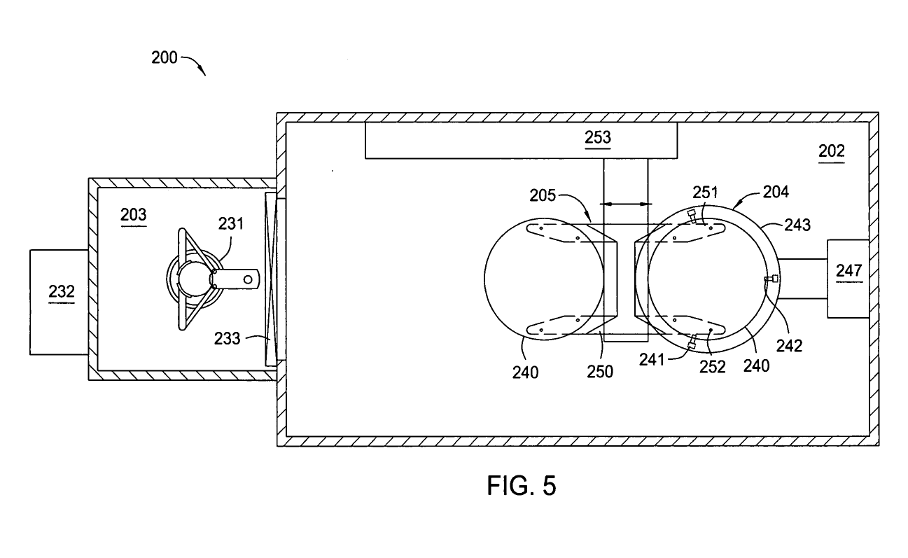

In one aspect, the support member 250 may be attached to a shaft 254 which is further attached to a slide mechanism 253 and a rotating mechanism 255. The rotating mechanism 255 is configured to rotate the support member 250 by 180° degrees back and forth such that the two sets of support blades 251 exchange their positions. In another aspect, the rotating mechanism 255 may be actuated by a pneumatic actuator which enables the support member 250 to rotate 180° degrees back and forth. In one aspect, the rotating mechanism 255 may be a servo motor. The slide mechanism 253 is configured to drive the support member 250 horizontally from an exchanging position, shown in FIG. 3, to a loading/unloading position, shown in FIG. 5. In the exchanging position, the support member 250 is cleared from the substrate boat 204 and the rotating mechanism 255 may rotate the support member 250. In the loading/unloading position, one of the two sets of the blades 251 are overlapping with the substrate boat 204 such that the blades 251 may pick up substrates from the substrate boat 204 and drop off substrates onto the substrate boat 204. The slide mechanism 253 may be actuated by hydraulic, pneumatic or electrical motor/lead screw mechanical actuators all well known in the art.

In one aspect, the support member 250 may be an “I” beam constructed with quartz or any suitable high temperature material that has small thermal expansion or similar thermal expansion to that of the material of the substrate boat 204, for instance, quartz, silicon carbide, or graphite, depending upon desired process characteristics. In one aspect, the support blades 251 may be constructed of alumina for stiffness or any suitable high temperature material such as, for instance, quartz, silicon carbide, or graphite, depending upon desired process characteristics.

It should be noted that shape of the support member 250, shape of the blades 251 and positions of the slide mechanism 253 and the rotating mechanism 255 are exemplary. Any other suitable shapes of the support member 250, suitable shapes of the blades 251 and suitable positions of the slide mechanism 253 and the rotating mechanism 255 are contemplated by the present invention.

The load lock 202 is generally connected to the pumping devices 207. In one aspect, the load lock 202 may be kept in a vacuum state all the time.

A slit valve opening 233 is generally attached to a side wall 221 of the load lock 202. Through the slit valve opening 233, a robot 231 disposed in a chamber 203 may insert (remove) substrates into (from) the load lock 202. In another aspect, the chamber 203 may be a factory front environment. The chamber 203 may further connect to one or more load ports 232 configured to store substrates. In one aspect, the robot 231 is capable of linear, rotational, and vertical movement and configured to shuttle substrates one by one. In another aspect, the robot 231 may be able to shuttle two substrates or a group of substrates.

In operation, the batch processing system 200 is in the process position, as shown in prior art, in which the substrate boat 204 loaded with a batch of substrates is inside the process chamber 201 which is sealed from the load lock 202. The gas delivery facilities 206 and the heating devices 209 may be employed by the system controller 208 to provide proper process conditions inside the process chamber 201. The rotating mechanism 248 may rotate the substrate boat 204 during the process. In one aspect, rotation speed of the substrate boat 204 may vary from about 0 to 10 revolutions per minute (rpm), but preferably between 1 rmp to 5 rpm. Inside the load lock 202, the batch handling tool 205 may be in the exchanging position. The set of the support blades 251 facing away from the substrate boat 204's loading/unloading position is loaded with a batch of unprocessed substrates. The other set of the blades 251 is empty. The slit valve opening 233 is closed and the load lock 202 is sealed from the chamber 203.

Upon finishing the process performed in the process chamber 201, the process chamber 201 may be pumped out. The lifting mechanism 247 may then lower the substrate boat 204 and the seal plate 244. The substrate boat 204 may be lowered to a certain distance such that each of the processed substrates in the substrate boat 204 is in a position slightly higher than a corresponding support blade 251 and each of the empty support blades 251 may slide under a corresponding processed substrate without contacting the adjacent processed substrates. In one aspect, the rotating mechanism 248 may rotate the substrate boat 204 such that the support rods 241 are not in the way of loading/unloading. Next, the batch handling tool 205 may be driven into its loading/unloading position, which features the empty set of support blades 251 is underneath the processed substrates in the substrate boat 204. The substrate boat 204 may be lowered a second distance such that the processed substrates are picked up by the empty set of support blades 251, as shown in FIG. 4. The batch handling tool 205 then slides back to its exchanging position and rotates 180° degrees so that the unprocessed substrates are facing the substrate boat 204. The batch handling tool 205 slides towards the substrate boat 204 again to the its loading/unloading position. The substrate boat 204 may be raised another distance, for example, the second distance, so that the unprocessed substrates on the support blades 251 are picked up by the support fingers 242 of the substrate boat 204. The batch handling tool 205 may slide back to its exchanging position. The substrate boat 204 may be raised back up into the process chamber 201 and the process chamber 201 may be sealed again to start another process cycle.

Now the processed substrates may be cooled down in the load lock 202 while resting on the support blades 251 if necessary. After the process chamber 201 is sealed from load lock 201, the load lock 202 may be vented if the chamber 203 is not vacuum chamber. The slit valve opening 233 may be opened and the robot 231 may shuttle the processed substrates to one of the load ports 232 and shuttle a new batch of unprocessed substrates the set of support blades 251 just holding the processed substrates. The slit valve opening 233 may be closed and the load lock 202 may be pumped down if necessary. The batch handling tool 205 will stand waiting for the finishing of the process in the process chamber 201. The above sequence may be repeated.

During the above process sequence, loading and unloading a substrate boat of a batch processing chamber are performed in batch. The batch processing chamber's idle time is reduced greatly compared to loading/unloading substrates one by one. The substrate boat stays hot between batches because the loading/unloading time is greatly shortened. For example, during an atomic layer deposition (ALD) process, a substrate boat may be heated to about 800 degrees Kelvin in a batch processing chamber. When the ALD process is finished, the substrate boat is transferred to a load lock chamber for unloading and reloading. When a substrate by substrate unloading and reloading process is finished, the temperature of the substrate boat usually drops to the temperature of the load lock which is generally the ambient temperature. Using a batch handling tool of the present invention, the temperature drop of a hot substrate boat can be reduced to less than 25%, preferably less than 15%. In case of the ALD process, a substrate boat heated to 800 degree Kelvin stays at a temperature higher than 600 degrees Kelvin when a batch handling tool finishes unloading and loading the substrate boat in a load lock of ambient temperature.

In one aspect, a batch handling tool may serve as a storage cassette especially during heating and cooling substrates. By combining a loading/unloading robot and a storage cassette in one batch handling tool, the present invention provides means to reduce system complexity and the number of motion axes of a batch processing system. Therefore, the batch handling tool of the present invention can further reduce cost and complexity of a batch processing system.

Mechanical translation, especially linear mechanism, is not desirable in a vacuum chamber. On the one hand, a vacuum and/or high temperature environment, in which many semiconductor processes are conducted, makes lubrication very difficult because the vacuum state tends to dry out lubricants. On the other hand, both lubricant and mechanical friction introduce particle contamination which is vital in a semiconductor process. A rotating mechanism is usually better than a linear mechanism in terms of lubrication and particle contamination. Especially, there are self-lubricating bearings available, for example, frelon lined ball-less ceramic bearings made of Zirconia. Therefore, replacing a linear mechanism with a rotating mechanism in a vacuum state may improve over all system performance. Embodiments of the present invention also include batch handling tools without requiring linear motions.

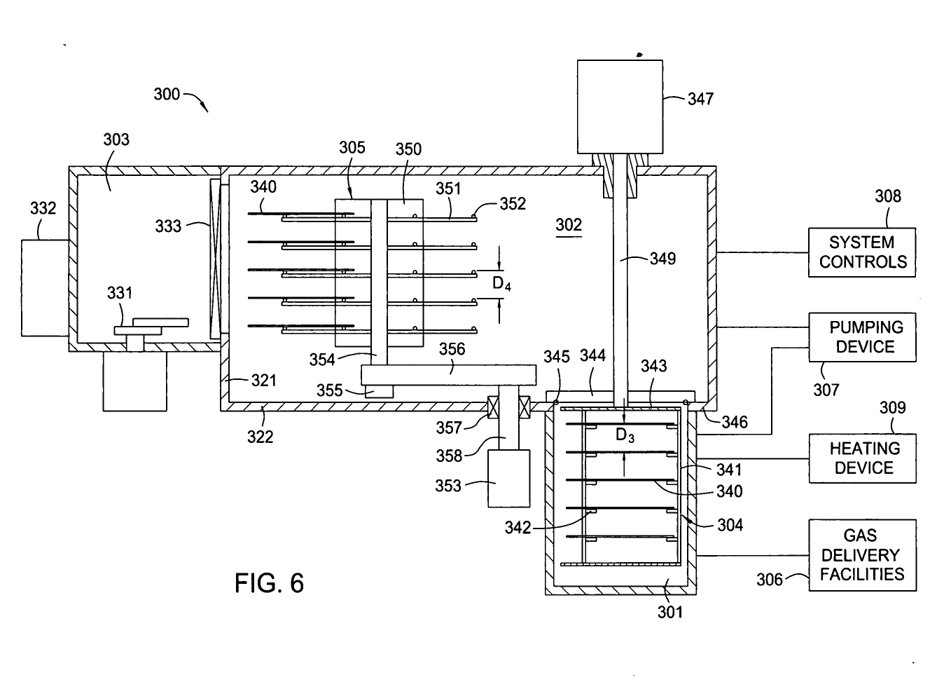

FIGS. 6-8 illustrate another embodiment of the present invention. Referring to FIG. 6, a batch processing 300 generally comprises a process chamber 301 configured to perform a batch semiconductor process, such as for example atomic layer deposition (ALD), chemical vapor deposition (CVD), plasma oxidation, ion implantation. A number of N2 substrates may be processed in a batch by the batch processing system 300. The process chamber 301 is generally in communication with gas delivery facilities 306 configured to deliver process materials, heating devices 309 configured to heat substrates and process materials, and pumping devices 307. In one aspect, the batch processing system 300 may have a system controller 308 configured to optimize the process.

The process chamber 301 is generally in selective fluid communication with a load lock 302 in which a substrate boat 304, configured to transfer a batch of substrates 340 in and out the process chamber 301 and support the substrates 340 during process, may be loaded/unloaded. In one aspect, the process chamber 301 and the load lock 302 may be vertically stacked together. In this case, the process chamber 301 is positioned below the load lock 302.

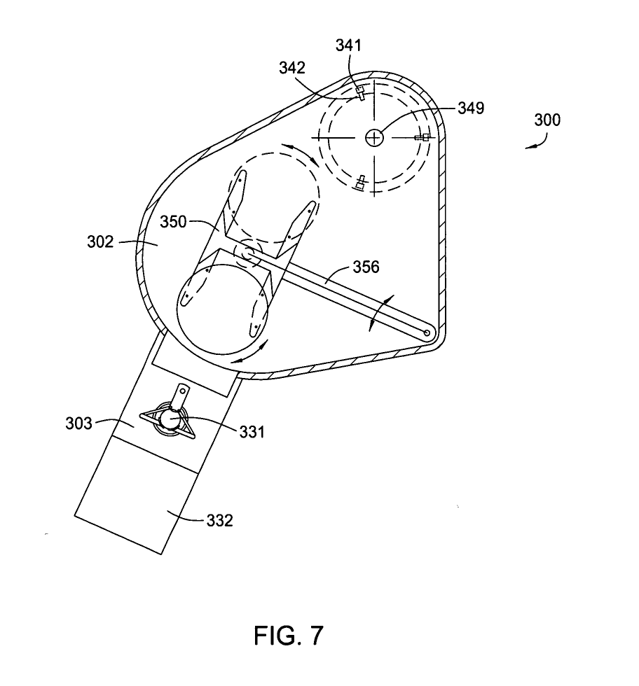

In one aspect, the substrate boat 304 is a vertical boat having a plurality of support rods 341 vertically attached to a base member 343. A set of support fingers 342 are generally formed on each of the plurality of the support rods 341. In one aspect, the set of support fingers 342 are evenly distributed along the length of the support rod 341 and a distance between a top surface of each support finger 342 to a top surface of its vertically neighboring finger 342 is D3. Referring now to FIG. 7, the support rods 341 are generally arranged along a perimeter of the base member 343. The perimeter is generally larger than a perimeter of a substrate and the support fingers 342 are generally reaching inwards such that a point near an edge of a substrate may be rested on tips of the support fingers 342. In one aspect, the support rods 341 may be arranged that two neighboring support rods 341 may have a distance larger than a diameter of a substrate so that the substrate may be loaded into or unloaded from the substrate boat 304 horizontally without touching the support rods 341. Referring back to FIG. 6, the support fingers 342 form a plurality of horizontal planes having an interval distance of D3, on which the batch of substrates 340 may be positioned. The base member 343 is generally connected to a shaft 349 through which the substrate boat 304 may be translated vertically and rotated. The substrate boat 304 may be constructed of any suitable high temperature material such as, for instance, quartz, silicon carbide, or graphite, depending upon desired process characteristics.

An O-ring structure 346 is generally disposed between the process chamber 301 and the load lock 302. In one aspect, a seal plate 344 configured to seal the process chamber 301 from the load lock 302 may be generally disposed around the shaft 349 above the base member 343. A quartz ring 345 is generally nested into a groove around an outer periphery of a bottom surface of the circular seal plate 344. In one aspect, the shaft 349 may connect to a lifting and rotating mechanism 347 configured to vertically translate the substrate boat 304 and to rotate the substrate boat 304. In one aspect, the lifting and rotating mechanism 347 may be actuated by hydraulic, pneumatic or electrical motor/lead screw mechanical actuators and a servo motor.

The substrate boat 304 and the seal plate 344 may be lowered that the substrate boat 304 is completely inside the process chamber 301 and the quartz ring 345 is in intimate contact with an inner lip of the O-ring structure 346. In this case, the seal plate 344 provides an almost complete seal between the process chamber 301 and the load lock 302 and the system 300 is in a process position as illustrated in FIG. 6. When the seal plate 344 is elevated, and the process chamber 301 is in fluid communication with the load lock 302, the system 300 is in a loading/unloading position.

An exemplary batch handling tool 305 is generally disposed in the load lock 302. The batch handling tool 305 generally comprises a support member 350 on which two sets of support blades 351 each configured to support a batch of substrates are mounted. Each set contains a number of N2 support blades 351. In one aspect, the two sets of support blades 351 may be mounted on the support member 350 in a back to back manner such that the two sets of support blades 351 switch positions if the support member rotates 180° degrees, as illustrated in FIG. 7. Contact pins 352 are generally formed on each of the support blades 351 such that each substrate held by the support blades 351 may be supported by at least three contact pins 352. The contact pins 352 reduce physical contact area between the support blades 351 and the substrates 340 thereon which reduces particle contamination. Referring back to FIG. 6, the support blades 351 are distributed along the length of the support member 350 at a distance D4 which is substantially equal to the distance D3 of the substrate boat 304. In one aspect, the support member 350 may be attached to a shaft 354 which is further attached to rotating mechanism 355 configured to rotate the support member 350 by 180° degrees back and forth such that the two sets of support blades exchange their positions. In one aspect, the rotating mechanism 355 may be actuated by a pneumatic actuator which enables the support member 350 to rotate 180° degrees back and forth. In one aspect, the rotating mechanism 355 may be a servo motor.

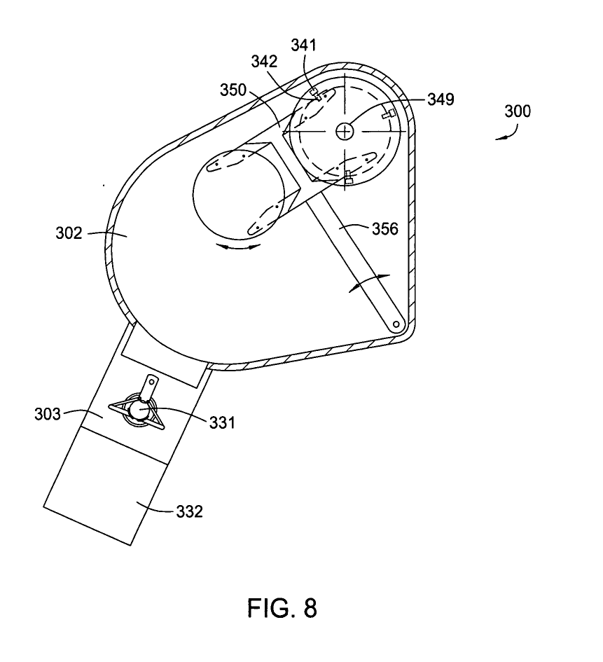

The shaft 354 and the rotating mechanism 355 are mounted on a rotary arm 356 which is connected to a rotary drive 353. The rotary drive 353 is configured to drive the support member 350 about the shaft 358 from an exchanging position, shown in FIG. 7, to a loading/unloading position, shown in FIG. 8. In the exchanging position, the support member 350 and blades 351 is cleared from the substrate boat 304 and the rotating mechanism 355 may rotate the support member 350. In the loading/unloading position, one of the two sets of the blades 351 are overlapping with the substrate boat 304 such that the blades 351 may pick up substrates from the substrate boat 304 or drop off substrates onto the substrate boat 304. In one aspect, the rotary drive 353 may be a servo motor.

In one aspect, the support member 350 may be an I beam constructed with quartz or any suitable high temperature material that has small thermal expansion or similar thermal expansion to that of the material of the substrate boat 304, for instance, quartz, silicon carbide, or graphite, depending upon desired process characteristics. In one aspect, the support blades 351 may be constructed of alumina for stiffness or any suitable high temperature material such as, for instance, quartz, silicon carbide, or graphite, depending upon desired process characteristics.

The use of the rotary arm 356 to drive the support member 350 and the blades 351 reduces physical contact inside the load lock 302, hence reduces particle contamination.

The load lock 302 is generally connected to the pumping devices 307. In one aspect, the load lock 302 may be kept in vacuum state all the time. A slit valve opening 333 is generally attached to a side wall 321 of the load lock 302. Through the slit valve opening 333, a robot 331 disposed in a chamber 303 may insert (remove) substrates into (from) the load lock 302. In one aspect, the chamber 303 may be a vacuum chamber so that the load lock 302 may be kept in vacuum condition all the time. In another aspect, the chamber 203 may be a factory front environment. The chamber 303 may further connect to one or more load ports 332 configured to store substrates. In one aspect, the robot 331 is capable of linear, rotational, and vertical movement and configured to shuttle substrates one by one. In another aspect, the robot 331 may be able to shuttle two substrates or a group of substrates.

In operation, the batch processing system 300 is in the process position, as shown in FIG. 6, in which the substrate boat 304 loaded with a batch of substrates is inside the process chamber 301 which is sealed from the load lock 302. The gas delivery facilities 306 and the heating devices 309 may be employed by the system controller 308 to provide proper process conditions inside the process chamber 301. The substrate boat 304 may be rotated during the process. In one aspect, rotation speed of the substrate boat 304 may vary from about 0 to 10 rpm, but preferably between 1 rmp to 5 rpm. Inside the load lock 302, the batch handling tool 305 may be in the exchanging position. The set of the support blades 251 facing away from the substrate boat 304's loading/unloading position is loaded with a batch of unprocessed substrates. The other set of the blades 351 is empty. The slit valve opening 333 is closed and the load lock 302 is sealed from the chamber 303.

Upon finishing the process performed in the process chamber 301, the process chamber 301 may be pumped out. The lifting and rotating mechanism 347 may then elevated the substrate boat 304 and the seal plate 344. The substrate boat 304 may be raised to a certain distance such that each of the processed substrates in the substrate boat 304 is in a position slightly higher than a corresponding support blade 351 and each of the empty support blades 351 may slide under a corresponding processed substrate without contacting the adjacent processed substrates. In one aspect, the lifting and rotating mechanism 347 may rotate the substrate boat 304 such that the support rods 341 are not in the way of the blades 351 when they enter the loading/unloading position. Next, the batch handling tool 305 may be pivoted to its loading/unloading position, which features the empty set of support blades 351 is underneath the processed substrates in the substrate boat 304. Since the support member 350 and the blades 351 enter/exit the substrate boat 304 along a curved trajectory, special consideration may be need to avoid contacts between the blades 351 and the support rods 341 when the handling tool 305 pivots in/out the loading/unloading position. In one aspect, the support rods 341 may be arranged to accommodate the curved trajectory. In one aspect, the substrate boat 304 may be rotated in an opposite direction as the handling tool 305 when the support member 350 and the blades 351 pivots into/out of the substrate boat 304.

After the handling tool 305 reaches the loading/unloading position, the substrate boat 304 may be lowered by a second distance such that the processed substrates are picked up by the empty set of support blades 351. The batch handling tool 305 then pivots back to its exchanging position and flips 180° degrees so that the unprocessed substrates are facing the substrate boat 304. The batch handling tool 305 pivots towards the substrate boat 304 again to the its loading/unloading position. The substrate boat 304 may be raised another distance, for example, the second distance, so that the unprocessed substrates on the support blades 351 are picked up by the support fingers 342 of the substrate boat 304. The batch handling tool 305 may pivot back to its exchanging position. The substrate boat 304 may be lowered into the process chamber 301 and the process chamber 301 may be sealed again to start another process cycle.

The processed substrates may be cooled down in the load lock 302 while resting on the support blades 351 if necessary. After the process chamber 301 is sealed from load lock 302, the load lock 302 may be vented if the chamber 303 is not vacuum chamber. The slit valve opening 333 may be opened and the robot 331 may shuttle the processed substrates to one of the load ports 332 and shuttle a new batch of unprocessed substrates the set of support blades 351 just holding the processed substrates. The slit valve opening 333 may be closed and the load lock 302 may be pumped down if necessary. The batch handling tool 305 will stand waiting for the finishing of the process in the process chamber 301. The above sequence may be repeated.

Driven by continuous demands for lowering COO and enabled by improved technologies, batch processing systems are able to process a large number of substrates in a batch. Many batch processing systems are able to process 25 substrates in a batch and have a capacity to increase the number to 100. A large batch number usually means a large or tall substrate boat and a large load lock to load and unload the substrate boat with a batch handling tool. A large load lock is usually not desirable for it takes extra time to pump out. One embodiment of the present invention provides a batch handling tool for loading/unloading substrates batch by batch which also requires reduced pumping volume.

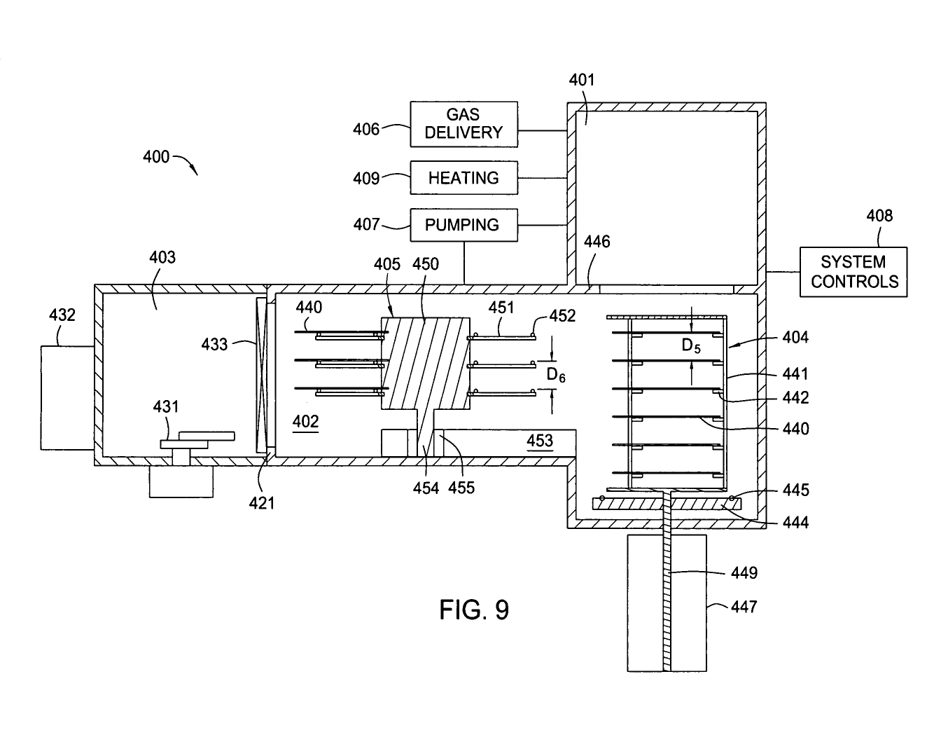

FIGS. 9-11 illustrate yet another embodiment of the present invention. Referring to FIG. 9, a batch processing system 400 generally comprises a process chamber 401 configured to perform a batch semiconductor process, such as for example atomic layer deposition (ALD), chemical vapor deposition (CVD), plasma oxidation, ion implantation. In one aspect, the batch processing system 400 may be able to process 2*N3 substrates in a batch. The process chamber 401 is generally in communication with gas delivery facilities 406 configured to deliver process materials, heating devices 409 configured to heat substrates and process materials, and pumping devices 407. In one aspect, the batch processing system 400 may have a system controller 408 configured to optimize the process.

The process chamber 401 is generally in selective fluid communication with a load lock 402 in which a substrate boat 404, configured to transfer a batch of substrates 440 in and out the process chamber 401 and support the substrates 440 during process, may be loaded/unloaded. In one aspect, the process chamber 401 and the load lock 402 may be vertically stacked together. In this case, the process chamber 401 is positioned above the load lock 402.

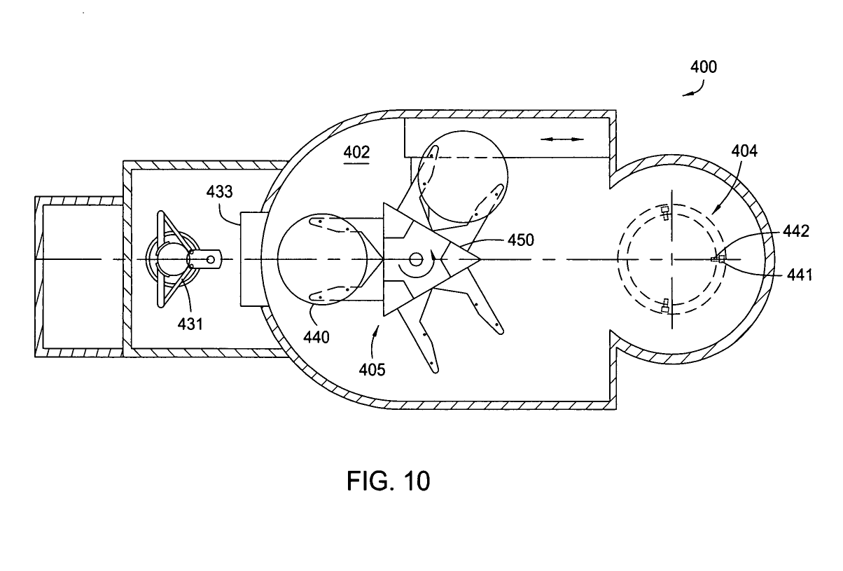

In one aspect, the substrate boat 404 is a vertical boat having a plurality of support rods 441 vertically attached to a base member 443. A set of support fingers 442 are generally formed on each of the plurality of the support rods 441. In one aspect, the set of support fingers 442 are evenly distributed along the length of the support rod 441 and a distance between a top surface of each support finger 442 to a top surface of its vertically neighboring finger 442 is D5. Referring now to FIG. 10, the support rods 441 are generally arranged along a perimeter of the base member 443. The perimeter is generally larger than a perimeter of a substrate and the support fingers 442 are generally reaching inwards such that a point near an edge of a substrate may be rested on tips of the support fingers 442. In one aspect, the support rods 441 may be arranged that two neighboring support rods 441 may have a distance larger than a diameter of a substrate so that the substrate may be loaded into or unloaded from the substrate boat 404 horizontally without touching the support rods 441. Referring back to FIG. 9, the support fingers 442 form a plurality of horizontal planes having an interval distance of D5, on which the batch of substrates 440 may be positioned. The base member 443 is generally connected to a shaft 449 through which the substrate boat 404 may be translated vertically and rotated. The substrate boat 404 may be constructed of any suitable high temperature material such as, for instance, quartz, silicon carbide, or graphite, depending upon desired process characteristics.

An O-ring structure 446 is generally disposed between the process chamber 401 and the load lock 402. In one aspect, a seal plate 444 configured to seal the process chamber 401 from the load lock 402 may be generally disposed around the shaft 449 below the base member 443. A quartz ring 445 is generally nested into a groove around an outer periphery of a bottom surface of the circular seal plate 444. In one aspect, the shaft 449 may connect to a lifting and rotating mechanism 447 configured to vertically translate the substrate boat 404 and to rotate the substrate boat 404. In one aspect, the lifting and rotating mechanism 447 may be actuated by hydraulic, pneumatic or electrical motor/lead screw mechanical actuators and a servo motor.

The substrate boat 404 and the seal plate 444 may be elevated that the substrate boat 404 is completely inside the process chamber 401 and the quartz ring 445 is in intimate contact with an inner lip of the O-ring structure 446. In this case, the seal plate 444 provides an almost complete seal between the process chamber 401 and the load lock 402 and the system 400 is in a process position. When the seal plate 444 is lowered, and the process chamber 401 is in fluid communication with the load lock 402, the system 400 is in a loading/unloading position.

An exemplary batch handling tool 405 is generally disposed in the load lock 402. The batch handling tool 405 generally comprises a support member 450 on which a plurality sets of support blades 451 each configured to support a batch of substrates are mounted. In one aspect, three sets of support blades 451 are mounted on the support member 450. Each set contains N3 support blades 451, i.e., each set of the support blades 451 is configured to transfer a half number of substrates in a batch. In one aspect, the three sets of support blades 451 may be mounted radically around the support member 350 such that every two sets of support blades 451 are 120 degrees apart, as illustrated in FIG. 10. Contact pins 452 are generally formed on each of the support blades 451 such that each substrate held by the support blades 451 may be supported by at least three contact pins 452. The contact pins 452 reduce physical contact area between the support blades 451 and the substrates 440 thereon which reduces particle contamination. Referring back to FIG. 9, the support blades 451 are distributed along the length of the support member 450 at a distance D6 which is substantially equal to the distance D5 of the substrate boat 404. In one aspect, the support member 450 may be attached to a shaft 454 which is further attached to rotating mechanism 455 configured to rotate the support member 450. In one aspect, the rotating mechanism 455 may comprise a servo motor.

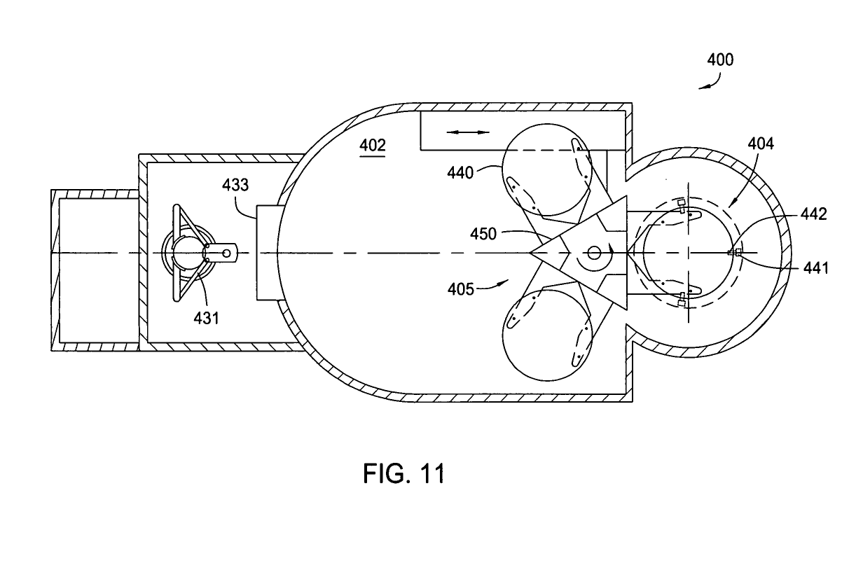

A slide mechanism 453 disposed in the load lock 402 may be connneted to the batch handling tool 405. The slide mechanism 253 is configured to drive the support member 450 horizontally from an exchanging position, shown in FIG. 10, to a loading/unloading position, shown in FIG. 11. In the exchanging position, the support member 450 is cleared from the substrate boat 404 and the rotating mechanism 455 may rotate the support member 450 and the support blades 451. In the loading/unloading position, one set of the blades 451 is overlapping with the substrate boat 404 such that the blades 451 may pick up substrates from the substrate boat 404 or drop off substrates onto the substrate boat 404. The slide mechanism 453 may be actuated by hydraulic, pneumatic or electrical motor/lead screw mechanical actuators all well known in the art.

In one aspect, the support member 450 may be an I beam constructed with quartz or any suitable high temperature material that has small thermal expansion or similar thermal expansion to that of the material of the substrate boat 404, for instance, quartz, silicon carbide, or graphite, depending upon desired process characteristics. In one aspect, the support blades 451 may be constructed of alumina for stiffness or any suitable high temperature material such as, for instance, quartz, silicon carbide, or graphite, depending upon desired process characteristics.

The load lock 402 is generally connected to the pumping devices 407. In one aspect, the load lock 402 may be kept in vacuum state all the time. A slit valve opening 433 is generally attached to a side wall 421 of the load lock 402. Through the slit valve opening 433, a robot 431 disposed in a chamber 403 may insert (remove) substrates into (from) the load lock 402. In one aspect, the chamber 403 may be a vacuum chamber so that the load lock 402 may be kept in vacuum condition all the time. In another aspect, the chamber 403 may be a factory front environment. The chamber 403 may further connect to one or more load ports 432 configured to store substrates. In one aspect, the robot 431 is capable of linear, rotational, and vertical movement and configured to shuttle substrates one by one. In another aspect, the robot 431 may be able to shuttle substrates in group.

In operation, the batch processing system 400 is in the process position, in which the substrate boat 404 loaded with a batch of substrates is inside the process chamber 401 which is sealed from the load lock 402. The gas delivery facilities 406 and the heating devices 409 may be employed by the system controller 408 to provide proper process conditions inside the process chamber 401. The lifting and rotating mechanism 447 may rotate the substrate boat 404 during the process. In one aspect, rotation speed of the substrate boat 404 may vary from about 0 to 10 revolutions per minute (rpm), but preferably between 1 rmp to 5 rpm. Inside the load lock 402, the batch handling tool 405 may be in the exchanging position, as shown in FIG. 10. Two sets of the support blades 451 are loaded with unprocessed substrate and the third set of the support blades 451 are empty. The slit valve opening 433 is closed and the load lock 402 is sealed from the chamber 403.

Upon finishing the process performed in the process chamber 401, the process chamber 401 may be pumped out. The lifting and rotating mechanism 447 may then lower the substrate boat 404 and the seal plate 444. The substrate boat 404 may be lowered to a certain distance such that each of the processed substrates in a top half of the substrate boat 404 is in a position slightly higher than a corresponding support blade 451 and each of the empty support blades 451 may slide under a corresponding processed substrate without contacting the adjacent processed substrates, as shown in FIG. 9. In one aspect, the lifting and rotating mechanism 447 may rotate the substrate boat 404 such that the support rods 441 are not in the way of loading/unloading. Next, the batch handling tool 405 may be rotated such that the empty set of support blades 451 face the substrate boat 404 directly. The batch handling tool 405 may be driven into its loading/unloading position, which features the empty set of support blades 451 is underneath a half of the processed substrates in the substrate boat 404. The substrate boat 404 may be lowered a second distance such that the half of the processed substrates are picked up by the empty set of support blades 451. The batch handling tool 405 then slides back to its exchanging position and rotate 120 degrees so that one set of support blades 451 with the unprocessed substrates are facing the substrate boat 404. The batch handling tool 405 slides towards the substrate boat 404 again to the its loading/unloading position. The substrate boat 404 may be raised another distance, for example, the second distance, so that the unprocessed substrates on the support blades 451 are picked up by the support fingers 442 of the substrate boat 404. The batch handling tool 405 the slides back to its exchanging position.

After the batch handling tool 405 moved out of the substrate boat 404, the substrate boat 404 may be raised again to a position where each of the processed substrates in a bottom half of the substrate boat 404 is in a position slightly higher than a corresponding support blade 451 and each of the empty support blades 451 may slide under a corresponding processed substrate without contacting the adjacent processed substrates. The batch handling tool 405 may be driven into its loading/unloading position again and pick up the bottom half of the processed substrates. The batch handling tool 405 then slides back to its exchanging position and rotate 120 degrees or 240 degree so that the second set of support blades 451 with the unprocessed substrates are facing the substrate boat 404. The batch handling tool 405 slides towards the substrate boat 404 again to the its loading/unloading position. The substrate boat 404 may be raised another distance, for example, the second distance, so that the unprocessed substrates on the support blades 451 are picked up by the support fingers 442 of the substrate boat 404. The batch handling tool 405 may slide back to its exchanging position and the substrate boat 404 is loaded with unprocessed substrates. The substrate boat 404 may be raised back up into the process chamber 401 and the process chamber 401 may be sealed again to start another process cycle.

The processed substrates may be cooled down in the load lock 402 while resting on the support blades 451 if necessary. After the process chamber 401 is sealed from load lock 402, the load lock 402 may be vented if the chamber 403 is not vacuum chamber. The batch handling tool 405 may rotate again so that one set of the support blades 451 with processed substrates facing the slit valve opening 433. The slit valve opening 433 may be opened and the robot 431 may shuttle the processed substrates to one of the load ports 432 and shuttle a first half of a new batch of unprocessed substrates the set of support blades 451 just holding the processed substrates. The batch handling tool 404 the pivots again so that the second set of the support blades 451 with processed substrates facing the slit valve opening 433. The robot 431 then shuttles the processed substrates to one of the load ports 432 and shuttle a second half of the new batch of unprocessed substrates the set of support blades 451 just holding the processed substrates. The slit valve opening 433 is then closed and the load lock 402 may be pumped down if necessary. The batch handling tool 405 will stand waiting for the finishing of the process in the process chamber 401. The above sequence may be repeated.

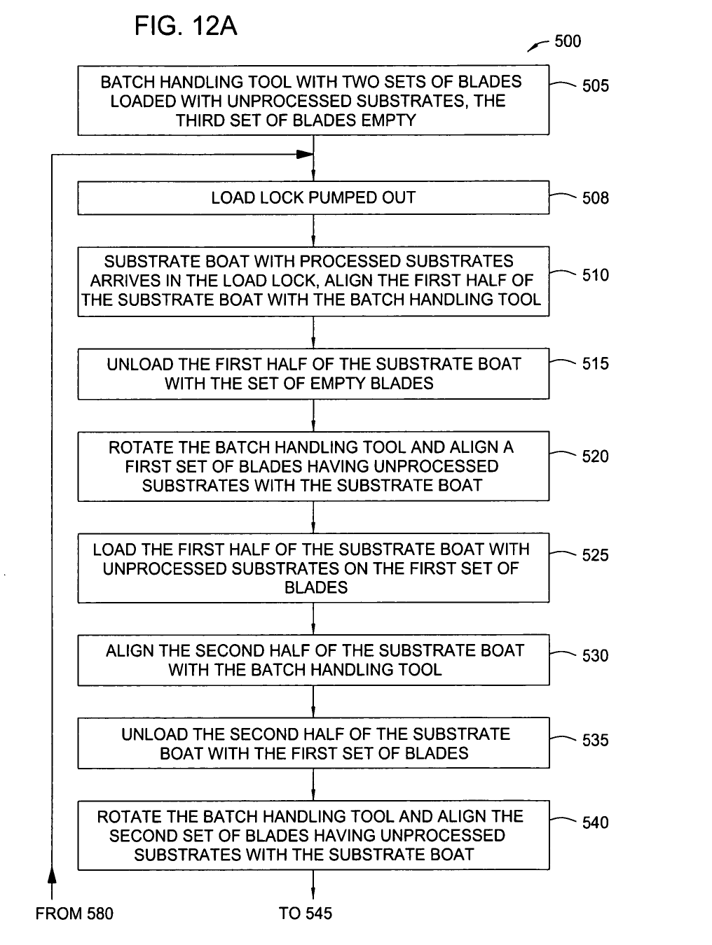

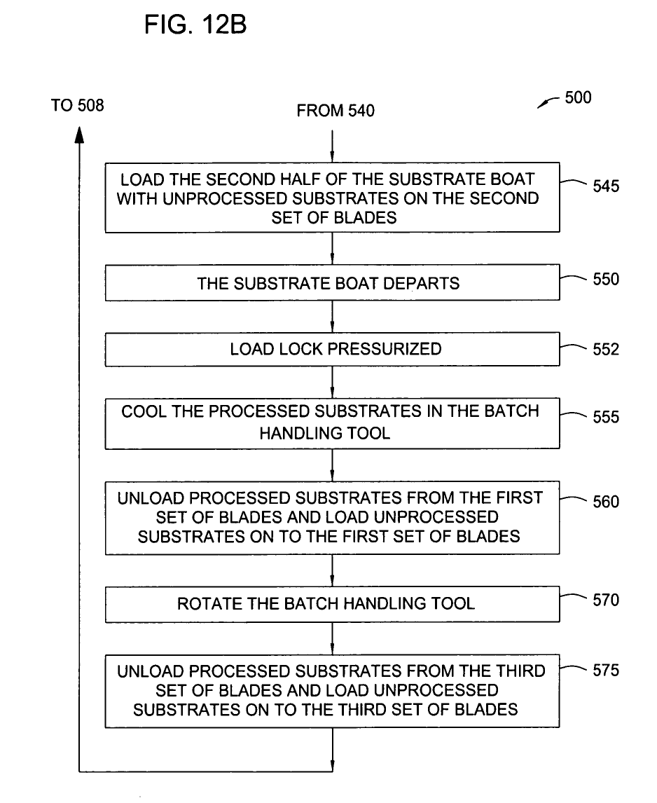

FIGS. 12A and 12B illustrate a loading/unloading sequence 500 for a batch handling tool with three sets of blades, each set of which has half the substrate carrying capacity of a corresponding substrate boat.

In step 505, the batch handling tool waits in a load lock with two sets of blades holding unprocessed substrates and the third set of blade empty.

In step 508, the load lock is pumped out to reach a required vacuum state.

In step 510, a substrate boat arrives in the load lock from a processing chamber with a batch of processed substrates and the first half of the substrate boat is aligned with the batch handling tool.

In step 515, the batch handling tool simultaneously unloads the first half of the substrate boat with the third (empty) set of blades.

In step 520, the batch handling tool rotates so that the first set of blades having unprocessed substrates is inline with the substrate boat.

In step 525, the batch handling tool simultaneously loads the unprocessed substrates on the first set of blades onto the first half of the substrate boat. Now the first set of blades is empty and inline with the substrate boat.

In step 530, the second half of the substrate boat is aligned with the batch handling tool, which may be done by adjusting the substrate boat position vertically.

In step 535, the second half of the substrate boat may be simultaneously unloaded by the batch handling tool which picks up the processed substrates with the first set of blades.

In step 540, the batch handling tool is rotated so that the second set of blades having unprocessed substrates is inline with the substrate boat.

In step 545, the batch handling tool simultaneously loads the unprocessed substrates on the second set of blades onto the second half of the substrate boat. Now the second set of blades is empty. The first and third set of blades have processed substrates and the substrate boat is loaded with unprocessed substrates.

In step 550, the substrate boats departs for the processing chamber where the unprocessed substrates may be processed.

Meanwhile, the processed substrates are stored in the batch handling tool. Optionally, the processed substrates may cool down on the batch handling tool, as described in step 555.

In step 552, the load lock is pressurized so that a factory interface robot can unload and reload the batch handling tool.

Next, the processed substrates on the batch handling tool are unloaded by a robot, for example, a factory interface robot, and a new batch of unprocessed substrates may be loaded onto two sets of blades and the third set of blades remains empty. Then the sequence may be repeated from step 510. Loading and unloading the batch handling tool may be performed by different sequences. Steps 560-580 provide one exemplary sequence.

In step 560, the processed substrates on the first set of blades are unloaded and unprocessed substrates from a new batch are unloaded onto the first set of blades. This unloading and loading process can be performed in various ways. The substrates may be handled individually or by batch. In one embodiment, a dual arm atmospheric robot may swap (unload the processed substrate then load the unprocessed substrate) each blades.

In step 570, the batch handling tool is rotated such that the third set of blades (with processed substrates) is in position for loading and unloading.

In step 575, the processed substrates are unloaded from the third set of blades and unprocessed substrates from a new batch are loaded onto the third set of blades. This unloading and loading process can be performed in various ways. In one embodiment, a dual arm atmospheric robot may swap (unload the processed substrate then load the unprocessed substrate) each blades.

Now two sets of blades are loaded with unprocessed substrates and the third set of blades is empty. Since the three sets of blades are similar to one another and interchangeable, the batch handling tool is in the same condition as in step 505. Therefore, the same sequence from step 510 to step 580 may be repeated.

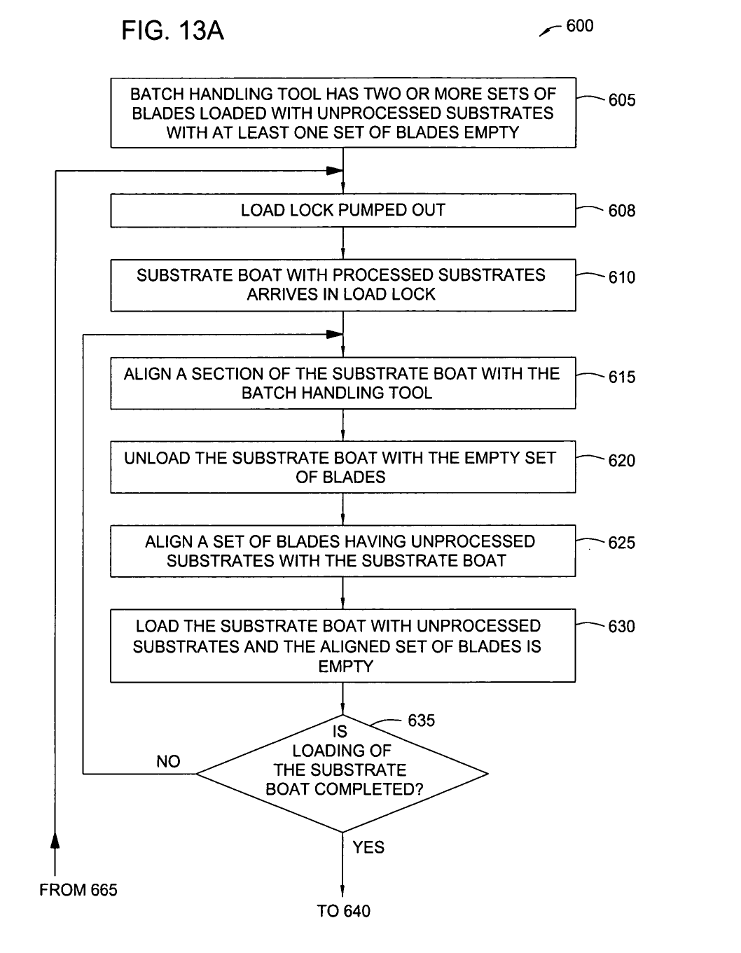

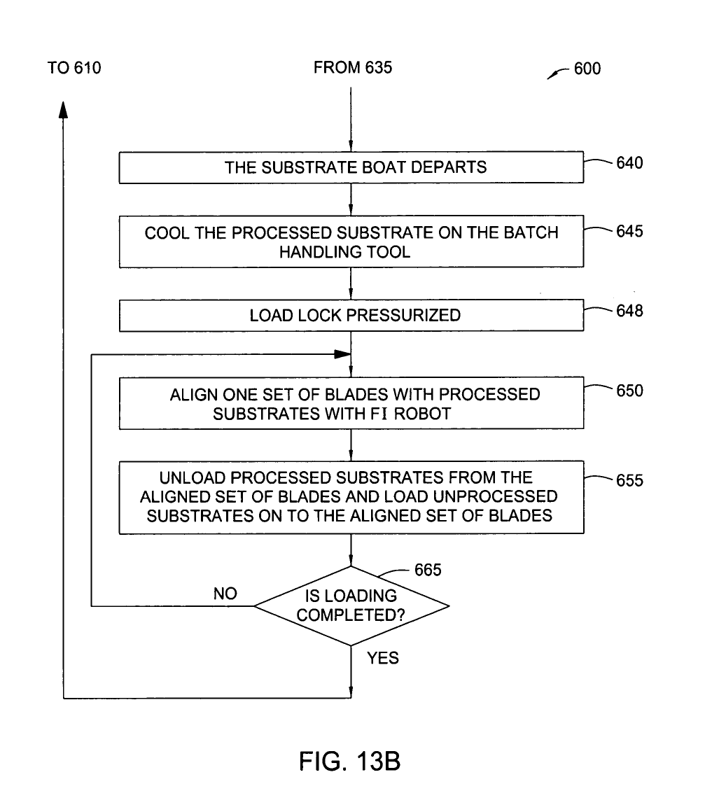

By using three sets of support blades each set configured to hold half a batch of substrates, a batch handling tool may reduce its height by about a half, therefore, reduce height of a load lock as well. It should be noted that more than three sets of support blades may be used in a batch handling tool to further reduce the load lock. Generally, the present invention can be adapted to batch handling tools with two or more sets of blades each configured to transfer two or more substrates simultaneously. FIGS. 13A and 13B illustrate a loading/unloading sequence 600 for such a batch handling tool having two or more sets of blades, each set of which has at least a portion of substrate carrying capacity of a corresponding substrate boat.

In step 605, the batch handling tool awaits in a load lock holding unprocessed substrates and at least one set of blade is empty.

In step 608, the load lock is pumped out to a required vacuum state.

In step 610, a substrate boat arrives in the load lock from a processing chamber with a batch of processed substrates.

In step 615, a section of the substrate boat is aligned with the batch handling tool. For a batch handling tool with two sets of blades, the section of the substrate boat includes the whole substrate boat.

In step 620, the batch handling tool simultaneously unloads aligned section of the substrate boat with the empty set of blades.

In step 625, the batch handling tool rotates so that a set of blades having unprocessed substrates is inline with the substrate boat.

In step 630, the batch handling tool simultaneously loads the unprocessed substrates on the aligned set of blades onto the section of the substrate boat. Now the aligned set of blades is empty.

Step 635 determines if loading of the substrate boat is completed. If not, the sequence goes back to step 615.

In step 640, the substrate boats loaded with unprocessed substrates departs for the processing chamber where the unprocessed substrates may be processed.

Meanwhile, the processed substrates are stored in the batch handling tool. Optionally, the processed substrates may cool down on the batch handling tool, as described in step 645.

In step 648, the load lock is pressured such that a factory interface robot may unload and reload the batch handling tool.

In step 650, a set of blades with processed substrates is aligned with an Fl robot. The alignment may be performed by rotating the batch processing tool.

In step 655, the processed substrates on the aligned set of blades are unloaded and unprocessed substrates from a new batch are loaded on the aligned set of blades. This unloading and loading process can be performed in various ways. The substrates may be handled individually or by batch. In one embodiment, a dual arm atmospheric robot may swap (unload the processed substrate then load the unprocessed substrate) each blades.

Step 665 determines if loading/unloading of the batch handling tool is complete. If not, the sequence goes back to step 650.

Now since the batch handling tool is loaded with unprocessed substrates, the same sequence from step 610 to step 665 may be repeated.

While the foregoing is directed to embodiments of the present invention, other and further embodiments of the invention may be devised without departing from the basic scope thereof, and the scope thereof is determined by the claims that follow.

1. A batch handling tool for supporting and transferring substrates during batch processing, comprising:
at least two sets of support blades configured to support the substrates;
a support member on which the at least two sets of support blades are mounted; and
a mechanism connected to the support member and configured to switch positions of the at least two sets of support blades and to move the support member.

2. The batch handling tool of claim 1, wherein the at least two sets of support blades are mounted radially on the support member and the mechanism comprises a rotation drive to rotate the at least two sets of support blades about a center axis of the support member.

3. The batch handling tool of claim 1, wherein three sets of support blades are mounted radially on the support member and their positions are switched by rotating the support member by at least one of a 120° and a 240°.

4. The batch handling tool of claim 1, wherein only two sets of support blades are mounted back to back the support member and their positions are switched by rotating the support member by 180°.

5. The batch handling tool of claim 1, wherein the drive comprises a linear translation configured to move the support member linearly.

6. The batch handling tool of claim 1, wherein the drive comprises a rotary arm configured to move the support member along an arc.

7. A batch processing system, comprising:
a process chamber;
a load lock in selective fluid communication with the process chamber;
a substrate boat configured to support and transfer at least two substrates between the process chamber and the load lock; and
a batch handling tool disposed in the load lock configured to load and unload the substrate boat at least two substrates at a time.

8. The system of claim 7, wherein the batch handling tool comprises:
at least two sets of support blades, each of which configured to unload and load the at least two substrates in the substrate boat;
a support member on which the at least two sets of support blades are mounted; and
a mechanism connected to the support member and configured to switch positions of the at least two sets of support blades and to move the support member.

9. The system of claim 8, wherein at least one set of the at least two sets of support blades are empty when the batch handling tool unload all the substrates from the substrate boat.

10. The system of claim 7, wherein the batch handling tool comprises:
two sets of support blades, each of which configured to load and unload all of the at least two substrates in the substrate boat;
a support member on which the two sets of support blades are mounted; and
a mechanism connected to the support member and configured to switch positions of the two sets of support blades and to move the support member.

11. The system of claim 10, wherein the mechanism comprises a linear drive configured to move the support member.

12. The system of claim 10, wherein the mechanism comprises rotary arm configured to move the support member.

13. The system of claim 10, wherein the two sets of support blades are mounted back to back on the support member and positions of the two sets of support blades are switched by rotating the support member by 180°.

14. The system of claim 7, wherein the batch handling tool comprises:
three sets of support blades, each of which configured to load and unload a half of the at least two substrates in the substrate boat;
a support member on which the three sets of support blades are mounted radically; and
a mechanism connected to the support member and configured to switch positions of the two sets of support blades and to move the support member.

15. The system of claim 7, further comprising:
a slit valve opening on the load lock through which a robot disposed out side the load lock can insert and remove substrates from the load lock.

16. A method for transferring and supporting substrates during batch processing, the method comprising:
loading a plurality of unprocessed substrates onto a batch handling tool having at least two sets of support blades;
receiving in the batch handling tool, in one or more batches, a plurality of processed substrates from a substrate boat; and
transferring the plurality of unprocessed substrates, in one or more batches, to the substrate boat.

17. The method of claim 16, wherein the batch handling tool rotates 180° between the receiving and the transferring.

18. The method of claim 16, wherein the receiving and the transferring are performed alternately.

19. The method of claim 18, wherein the batch handling tool rotates 120° or 240° between the receiving and the transferring.

20. The method of claim 16, wherein the batch handling tool has three sets of support blades, wherein the receiving occurs in two batches, and the transferring occurs in two batches.

21. A method for processing a plurality of substrates in a batch processing chamber, the method comprising:
processing a first plurality of substrates in a substrate boat at a first temperature;
moving the substrate boat from the batch processing chamber to a substrate loading position; and
unloading the first plurality of substrates from the substrate boat and loading a second plurality of substrates onto the substrate boat while the substrate boat cools to a second temperature, wherein the second temperature is reduced from the first temperature by less than 25% of the first temperature.

22. The method of claim 21, further comprising moving the substrate boat from the substrate loading position to the batch processing chamber.

23. The method of claim 21, wherein the unloading and the loading are performed in one or more batches.

24. The method of claim 21, further comprising:
prior to the moving, pumping out the substrate loading position to a vacuum state.
